(19) United States
(12) Patent Application Publication
(10) Pub. No.: US 2023/0152705 A1
(43) Pub. Date: May 18, 2023

(54) UV Treatment of EUV Resists

(71) Applicant: Tokyo Electron Limited, Tokyo (JP)

(72) Inventors: Steven Grzeskowiak, Albany, NY (US); Angelique Raley, Albany, NY (US)

(21) Appl. No.: 17/455,365

(22) Filed: Nov. 17, 2021

(51) Int. Cl. G03F 7/20

(52) U.S. Cl. CPC G03F 7/2022; G03F 7/2004; G03F 7/0042

(57) ABSTRACT

A method includes loading a substrate with a resist including a pattern exposed with a first dose of UV light in the extreme ultraviolet (EUV) radiation region of the UV spectrum onto a developer track; blanket exposing the substrate with a second dose of ultraviolet light radiation in a first UV exposure module; and after the blanket exposing, developing the pattern.

### TECHNICAL FIELD

The present invention relates generally to EUV resists and in particular to ultraviolet (UV) treatment of extreme ultraviolet (EUV) resists.

### BACKGROUND

As semiconductor geometries scale to increasingly smaller pitches, the wavelength of light used to print these patterns necessarily gets shorter and shorter. According to the semiconductor technology roadmap, the plan was to introduce EUV scanners into manufacturing in 2007. Technical challenges encountered in making EUV sources with adequate intensity and technical challenges encountered in making EUV photo resists with sufficient sensitivity to EUV radiation delayed the introduction of EUV photolithography until 2019.

The recent development of organometallic resists with increased sensitivity and EUV sources with increased intensity has enabled the introduction of EUV patterning into semiconductor manufacturing at the 5 nm and 7 nm transistor nodes.

### SUMMARY

A method includes loading a substrate with a resist including a pattern exposed with a first dose of UV light in the extreme ultraviolet (EUV) radiation region of the UV spectrum onto a developer track; blanket exposing the substrate with a second dose of ultraviolet light radiation in a first UV exposure module; and after the blanket exposing, developing the pattern.

A method of forming a pattern on a substrate with a first dose of UV light in the extreme ultraviolet (EUV) region of the UV spectrum includes placing the substrate within an EUV lithography tool, an exposed outer surface of the substrate including an EUV resist; exposing the EUV resist to EUV light transmitted through an optical mask including a pattern to be transferred; blanket exposing the EUV resist on the substrate with a second dose of UV light; and after the blanket exposing, developing the EUV resist to form the pattern to be transferred.

A method of processing a substrate includes having an organometallic photoresist disposed on a layer to be patterned formed on the substrate, the organometallic photoresist including alkyl ligands attached to metal oxide particles; forming photoproducts by removing a first fraction of the alkyl ligands from portions of the organometallic photoresist to be developed; condensing the photoproducts to form a metal oxide network in the exposed portion of the organometallic photoresist; removing a second fraction of the alkyl ligands from the metal oxide network in the organometallic photoresist from the exposed portion and from the unexposed portion of the organometallic photoresist; and after removing the second fraction of the alkyl ligands, developing the organometallic photoresist to form a patterned organometallic photoresist.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1A is a flow diagram describing the formation of patterns in extreme ultraviolet EUV resist in accordance with embodiments;

FIGS. 1B-1F are cross sectional views of a semiconductor device during various stages of fabrication and depicting steps in the flow diagram of FIG. 1A;

FIG. 2A-2C and FIG. 3 describe chemical reactions that occur in organometallic EUV photoresist during exposure to UV and EUV light;

FIG. 4 is a graph comparing the critical dimensions (CDs) of geometries formed in an organometallic EUV resist using EUV exposure only versus using EUV exposure plus blanket UV exposure in accordance with an embodiment;

FIG. 5 is a cross sectional view of a layer of EUV resist with graphs of EUV dose and of EUV and blanket UV dose superimposed in accordance with an embodiment;

FIG. 6 are post develop cross sectional views of an EUV resist geometry formed with an EUV dose only versus an EUV resist geometry formed with an EUV dose and a blanket UV dose in accordance with an embodiment;

FIG. 7 is a graph comparing the critical dimensions (CDs) of a geometry formed in an organometallic EUV resist using a wet develop process versus using a dry develop process after EUV and blanket UV exposure in accordance with an embodiment;

FIG. 8 is a flow diagram describing the major steps in a method for selecting an EUV dose plus a blanket UV dose that improves throughput in an EUV stepper in accordance with an embodiment;

FIG. 9 is a graph of the thickness of EUV resist remaining after a timed develop versus UV dose in accordance with an embodiment; and

FIG. 10 is a flow diagram describing the major steps in a method for selecting a blanket UV dose that improves scumming in an EUV pattern in accordance with an embodiment.

### DETAILED DESCRIPTION OF ILLUSTRATIVE EMBODIMENTS

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

Although much progress in EUV tools have been made in the past decade, the EUV stepper is still a bottleneck tool in manufacturing due to its low throughput. The number of wafers that can be processed through an EUV stepper is limited by the intensity of the EUV light source and by the sensitivity of the EUV resist. The process window for scumming in the EUV pattern during developing can be narrow especially in areas with tight pitches.

Embodiments of this application disclose methods for forming patterns by exposing extreme ultraviolet (EUV) resist patterns with blanket UV light. Embodiments of this application disclose methods of reducing cycle time through EUV steppers when forming patterns in EUV resists. Embodiments of this application disclose methods of improving contrast and reducing scumming when forming patterns in EUV resists.

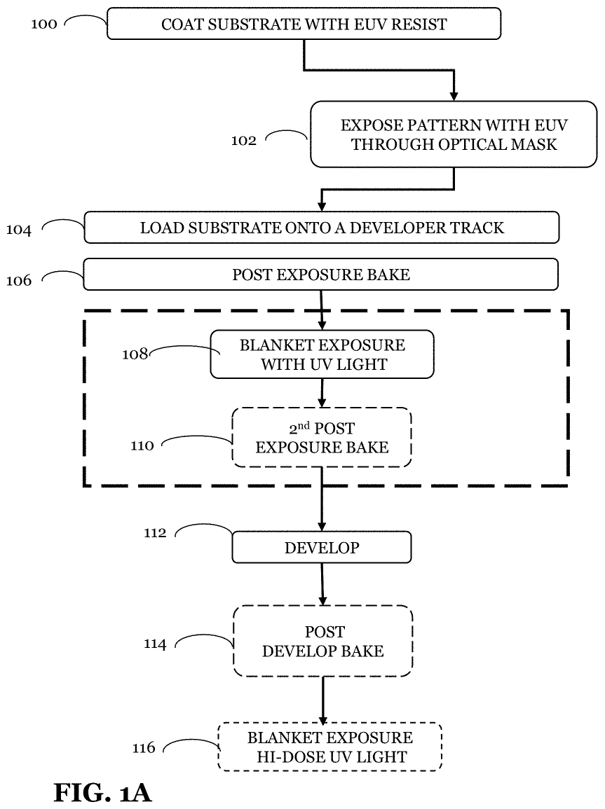

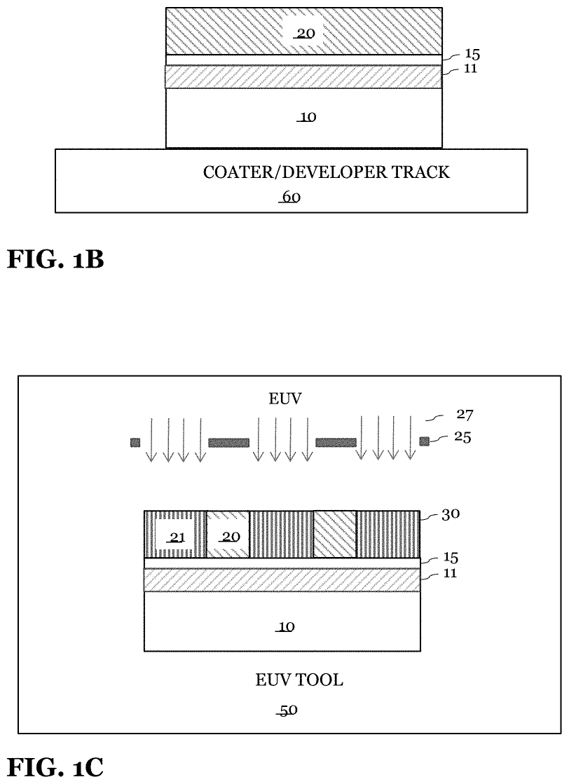

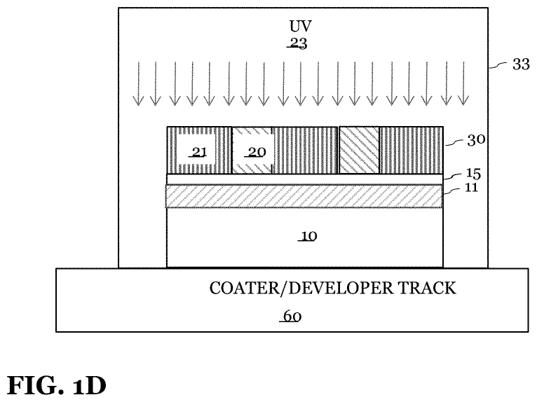

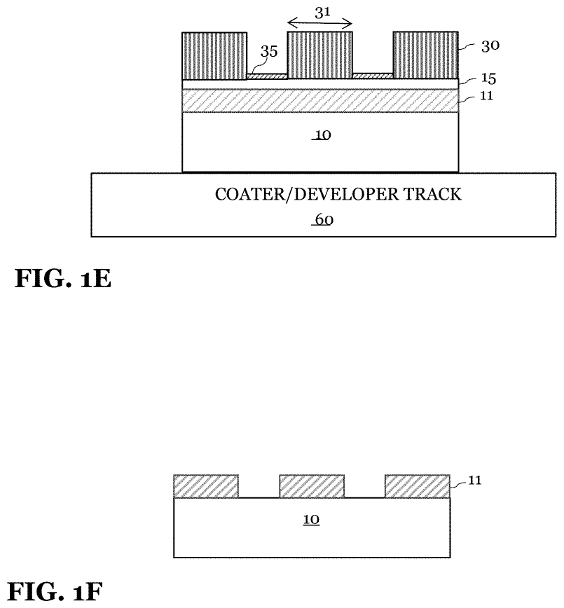

FIG. 1A is a flow diagram describing the major steps in forming a pattern in extreme ultraviolet (EUV) resist in accordance with an embodiment. FIGS. 1B through 1F are cross sectional views further describing some of the major steps in the flow diagram in FIG. 1A.

The process includes a coating process to coat the substrate with an EUV photoresist (block 100). As is illustrated in FIG. 1B, in semiconductor manufacturing the semiconductor wafer substrate 10 is coated with EUV resist 20 in a coater/developer track 60. A layer to be patterned 11 such as a hard mask layer can be deposited on the substrate 10 prior to coating with EUV resist. The substrate 10 may already include a number of layers including doping regions for forming active devices in various embodiments. Additional layers 15 such as antireflective layers and adhesion promoting layers can be deposited on the layer to be patterned 11 prior to coating the substrate 10 with EUV resist 20.

The EUV resist 20 can be a chemically amplified (CAR) EUV resist, a photo acid generated (PAG) EUV resist, or an organometallic EUV resist. Organometallic EUV resists 20 comprise metal oxide cores surrounded by organic alkyl groups covalently bonded to the metal oxide cores. The metal oxide core can be tin oxide, hafnium oxide, zinc oxide, and zirconium oxide for example. The metal atoms in the metal oxide cores absorb EUV light more strongly than the carbon and oxygen atoms in organic polymer resists making the organometallic EUV resists more EUV sensitive.

Referring next to block 102 and to FIG. 1C, the substrate 10 is transferred to a EUV photolithography stepper 50 where a dose of EUV light 27 is projected through an optical mask 25 to form a pattern 30 in the EUV resist 20. In an organometallic EUV resist 20, the exposed portion 21 of the EUV resist becomes insoluble in developer while the unexposed portion 20 of the EUV resist remains soluble. Either a wet develop process or a dry develop process can be used to develop the pattern.

As next illustrated with block 104 the substrate can be returned to the coater/developer track 60 to undergo a post exposure bake. The substrate 10 is typically baked for 1 to 3 minutes in air at a temperature of 50° C. to 250° C. The post EUV exposure bake conditions are selected to promote a degree of crosslinking in the exposed resist for improved contrast and reduced line edge roughness (LER).

Normally when forming a pattern in EUV resist 20, the next step is to develop the pattern (block 112). In accordance with an embodiment, the EUV patterning process is improved by introducing a blanket UV exposure step (block 108) prior to the develop step (block 112).

FIG. 1D illustrates the substrate next undergoing a blanket UV treatment in accordance with embodiments.

As illustrated in FIG. 1D, the substrate 10 with patterned geometries 30 (exposed EUV resist 21 and unexposed EUV resist 20) is loaded back into the coater/developer track 60 and subjected to a blanket exposure of UV light 23 in a first UV exposure module 33.

The blanket UV exposure 23 is performed without any optical mask and therefore regions that have been exposed previously to the EUV light 27 and regions that have not been exposed to the EUV light 27 are both exposed. Because of this blanket exposure, there is almost no additional cost for this process.

In various embodiments, the wavelength of light during the blanket UV exposure 23 ranges from about 130 nm to about 300 nm, for example between 150 nm and 200 nm in one embodiment and between 130 nm and 300 nm in another embodiment. In various embodiments, the dose of UV light during the blanket UV exposure 23 is between about 1 mJ/cm2 and about 100 mJ/cm2, e.g., between 1 mJ/cm2 and 100 mJ/cm2.

FIG. 1E illustrates a cross sectional view of the substrate 10 after the soluble portions of the EUV resist 20 are removed during development. The insoluble geometries of pattern 30 remain. An embodiment blanket UV light exposure can improve EUV stepper throughput by reducing the dose of EUV light 27 required to reach a target critical dimension (CD) 31. The embodiment blanket UV light exposure 23 improves the range over which the CD can be tuned. As illustrated in FIG. 1E, scum 35 may remain especially in regions with tight pitches after organometallic EUV resists 20 are developed. The embodiment blanket UV exposure 23 advantageously may be used to reduce or eliminate the scum 35 formed after developing (block 112). In addition, the embodiment blanket UV exposure 23 may also improve contrast.

An optional post blanket UV exposure bake (PEB) (block 110) may be performed after the blanket UV exposure step (block 108) and before the develop step (block 112). This PEB can be performed by subjecting the wafer to baking process for 1 to 3 minutes in air or nitrogen at a temperature of 50° C. to 250° C. The post blanket UV exposure bake conditions are selected as the best compromise between reduced scumming, improved line edge roughness (LER), improved contrast, and reduction of the EUV dose required to hit target CD.

In various embodiments, either a wet develop process or a dry develop process may be used for developing in block 112. In case of wet developing, droplets of the developer solution can become trapped in the deep trenches between minimum pitch lines after developing. Surface tension from these droplets can deform these narrowly spaced lines causing pattern distortion and bridging. In some cases, wet developing can cause tall, narrow resist lines to topple over.

In various embodiments, a dry develop process may be used to avoid the above issues with wet developing. For example, EUV organometallic resists can be dry developed using a mixture of hydrogen gas and a halogen gas such as bromine, chlorine, or hydrogen halide such as HBr, HCl, or HI. The develop time may be reduced by first passing the gases through a remote plasma to generate reactive hydrogen and halogen radicals.

After developing, an optional post development bake can be performed (block 114). The post develop bake process may also be a blanket UV exposure that additionally cross links the resist to reduce resist erosion during a subsequent plasma etching step (UV hardening). The post development bake can also be a high temperature bake (hardbake) that degases the resist and stabilizes the pattern against high temperatures such as those generated in high current implant steps.

After developing, if scum 35 (FIG. 1E) is present, an optional blanket exposure with a high dose of UV light can be performed to remove the scum 35 (block 116). When the scum 35 residue in EUV patterns is largely composed of carbon, ozone generated by a UV light exposure may be used to remove the scum effectively. In various embodiments, a dose of UV light more than 80 mJ/cm², and in one embodiment, more than 100 mJ/cm², in air ambient can remove carbonaceous scums. In various embodiments, the wavelength of light during the optional blanket exposure ranges from about 130 nm to 300 nm, for example between 150 nm and 200 nm in one embodiment and 130 nm to 300 nm in another embodiment. The wavelength of light during the optional blanket exposure in block 116 may be different from the wavelength of light during the prior blanket exposure described in block 108. In one embodiment, the wavelength of light during the optional blanket exposure in block 116 is less than the wavelength of light during the prior blanket exposure described in block 108. In another embodiment, the optional blanket exposure is at a similar or lower wavelength when compared to the prior UV exposure since UV wavelengths shorter than 240 nm create ozone via photolysis of oxygen molecules. The UV light breaks bonds between carbon atoms forming active sites on the carbon atoms. Ozone generated in the ambient air by the UV light reacts with the carbon active sites to form gaseous oxidized carbon products such as carbon monoxide and carbon dioxide.

In embodiment methods for forming a pattern in EUV resist, the EUV resist 20 (FIG. 1B) receives a first UV exposure with EUV light 27 (FIG. 1C) projected through an optical mask 25 comprising the pattern 30 to be transferred to the substrate 10. The EUV light 27 used for the first exposure is in the extreme ultraviolet (EUV) region of the UV spectrum (about 10 nm to 120 nm, for example, 13.5 nm). This short wavelength is needed to print the narrow geometries and tight pitches on the mask 25. After printing the pattern with EUV light 27, the EUV resist receives a second UV exposure 23 (FIG. 1D) with longer wavelength (130 nm to 300 nm) UV light without a mask.

FIG. 1F illustrates the substrate 10 after an etching process transfers the photo resist pattern 30 into the hard mask layer 11. After the EUV resist pattern 30 is transferred into the hard mask layer 11, the EUV resist pattern 30 and the underlying intervening layers 15 are removed.

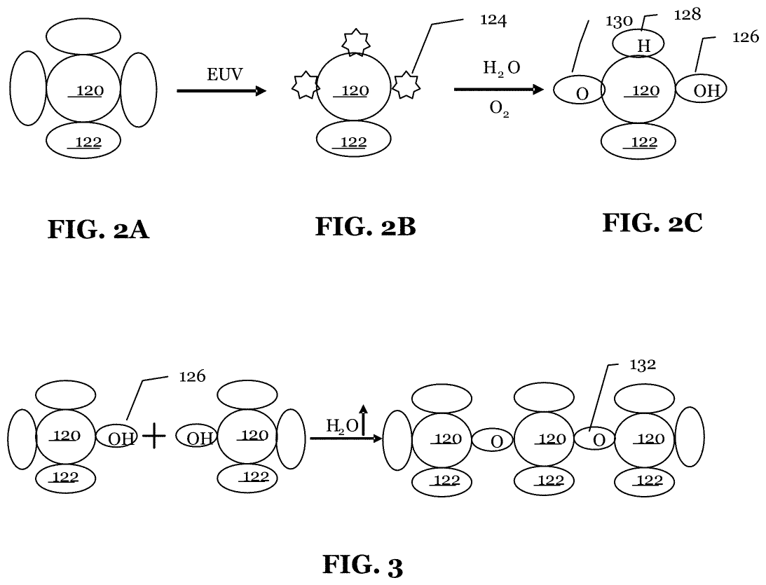

FIGS. 2A-2C and FIG. 3 illustrate chemical reactions that may occur in organometallic EUV photo resist during UV and EUV exposure.

Organometallic resists are composed of metal oxide cores 120 surrounded by organic alkyl ligands 122 as illustrated in FIG. 2A. The ligands 122 are bonded to the cores 120. As illustrated in FIG. 2B, in regions exposed with EUV or UV light, bonds between the ligands 122 and the cores 120 may be broken releasing the ligands 122 as gaseous molecules that diffuse away. This is because both UV and EUV light have the energy to break the bonds between the ligands 122 and the cores 120.

Active sites 124, formed on the core 120 where ligands 122 have been removed, react with oxygen molecules and water molecules in the ambient air to form bonds between the core 120 and hydrogen atoms 128, oxygen atoms 130, and hydroxy groups 126. With increased exposure to UV or EUV light, the concentration of cores 120 with attached hydroxy groups 126 increases.

As is illustrated in FIG. 3, when cores 120 with attached hydroxy groups 126 become sufficiently concentrated, adjacent cores 120 with attached hydroxy groups 126 can undergo a condensation reaction that splits out a water molecule and joins the two cores 120 together with an oxygen bridge 132. At high concentrations, multiple cores 120 bridge together to form two-dimensional (2-D) and three-dimensional (3-D) metal oxide networks. These metal oxide networks may be insoluble in developer, for example.

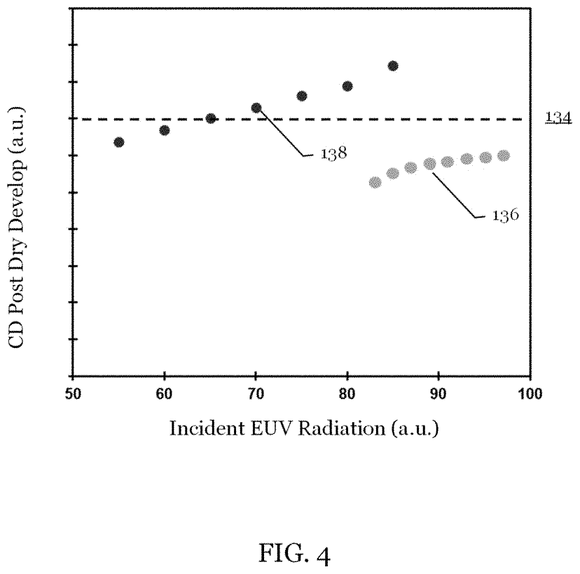

FIG. 4 is a graph comparing the linewidths (critical dimensions or CDs) of geometries in an EUV organometallic resist formed using EUV exposure only with CDs of geometries in the EUV organometallic resist formed using EUV exposure and a blanket UV exposure described in various embodiments. The incident EUV radiation and the CD after a dry develop process obtained from experimental data are shown in arbitrary units for illustration purposes.

The first dataset 136 represents CDs obtained by varying the EUV exposure without any additional UV exposure. The second dataset 138 represents CDs obtained by varying the EUV exposure with a fixed blanket UV exposure.

As illustrated handily in FIG. 4, a target CD 134 can be realized using a much lower EUV dose when combined with a blanket UV light as described in embodiments of this disclosure. In contrast, in the absence of the blanket UV exposure, with EUV light only, the target CD 134 may not even be achievable with even a much larger dose (or at best achieved with a 2× larger EUV dose in some cases). As previously described, the high dose needed for a conventional EUV exposure is a bottleneck during manufacturing. A reduction in EUV dose while still achieving target exposure and thereby target CD enables more wafers to be run through the bottleneck tool per hour.

In addition, using embodiments of the invention, the sensitivity range to CD can be improved. Thus, target CDs spread over a larger range can be achieved with the same process by simply changing the EUV dose, which can be very useful in manufacturing/design.

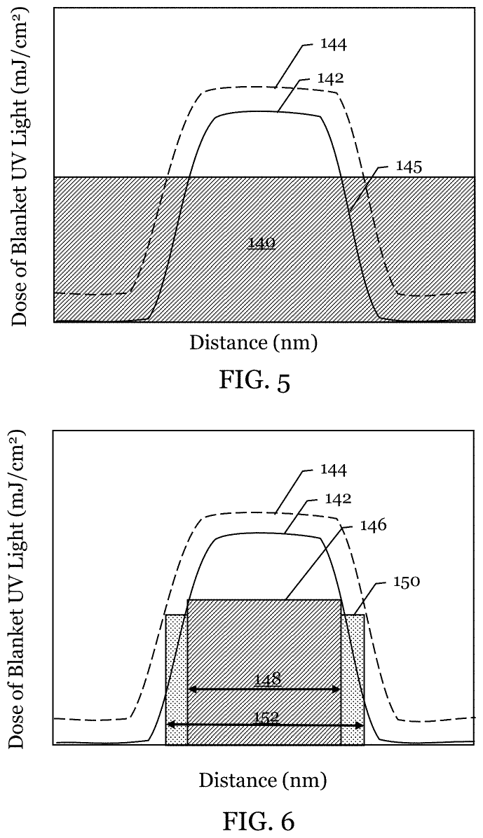

FIGS. 5 and 6 illustrate using the additional blanket UV dose to reach a critical dimension while lowering EUV dose.

FIG. 5 is a cross sectional view of a layer of EUV resist 140. Superimposed on the layer of EUV resist 140 is a graph 142 of the dose of EUV light projected through an opening in a photomask. The EUV dose is low on the sides of the EUV resist 140 where it is blocked by the mask and high in the middle of the EUV resist 140 where it is not blocked. The EUV light dose drops off with a steep slope in the transition region 145 where it transitions from high dose in the mask opening to low dose at the edges of the patterned geometry. The graph is adjusted so that the dose for the develop threshold coincides with the surface of the EUV resist 140. When the EUV dose is greater than the develop threshold as it is in the mask opening, the exposed EUV resist is rendered insoluble in developer. When the EUV dose is less than the develop threshold, as is on the sides of the resist where the EUV it is blocked by the photomask, the EUV resist remains soluble and develops away. Blanket UV exposure 144 applies a uniform dose across the EUV resist 140. In the middle of the EUV resist 140 where the EUV dose is high, the blanket UV dose adds UV exposure and makes the EUV resist 140 even more insoluble. At the sides of the EUV resist 140, the added blanket UV dose is not sufficient to reach the develop threshold, so the EUV resist 140 remains soluble in developer. In the transition region 145, where the dose rapidly drops off, the blanket UV exposure adjacent to the edges of the insoluble EUV geometry adds sufficient UV dose to push the EUV resist 140 above the develop threshold. EUV resist adjacent to the insoluble EUV geometry now becomes insoluble increasing the CD of the insoluble EUV geometry.

FIG. 6 compares the post develop CD 148 of a EUV resist geometry 146 exposed with EUV dose only 142 versus the post develop CD 152 of an EUV resist geometry 150 exposed with EUV and blanket UV exposures 144. The post develop CD 152 of EUV resist geometry 150 is larger than the post develop CD 148 of EUV resist geometry 146. As the blanket UV dose is increased, the post develop CD 152 is increased.

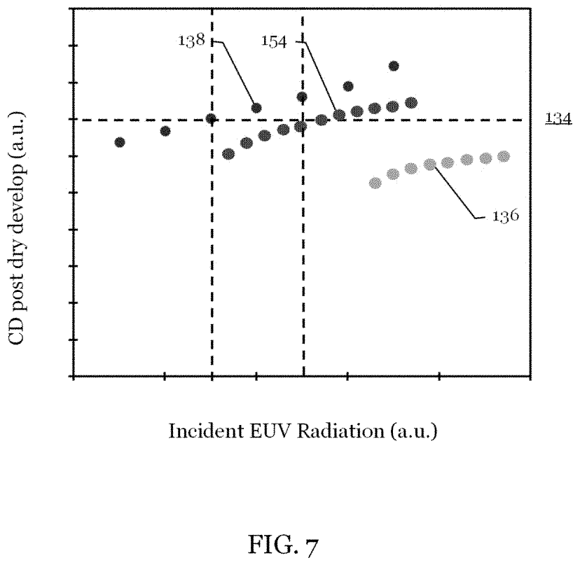

FIG. 7 is a graph comparing the linewidths (critical dimensions or CDs) of geometries in an EUV organometallic resist formed using EUV exposure only with CDs of geometries in the EUV organometallic resist formed using EUV exposure and a blanket UV exposure after a dry develop and wet develop process as described in various embodiments. The CDs obtained from experimental data are shown in arbitrary units for illustration purposes.

In FIG. 7, the CDs of a third dataset 154 of geometries formed with a wet develop process after EUV and blanket UV exposure are compared with the CDs of the second dataset 138 formed with a dry develop process. Like the dry develop CDs of the second dataset 138, a wet develop process may also be used to achieve the target CD 134 with a lower EUV dose than CDs of the first dataset 136 achievable with using only EUV exposure. In this example, a wet develop process requires about a 50% higher EUV dose to achieve a target CD than a dry develop process. In this example, with a wet develop process, the variation in CD is less than the dry develop process, e.g., about 25% less variation in CD is obtained with the wet develop process.

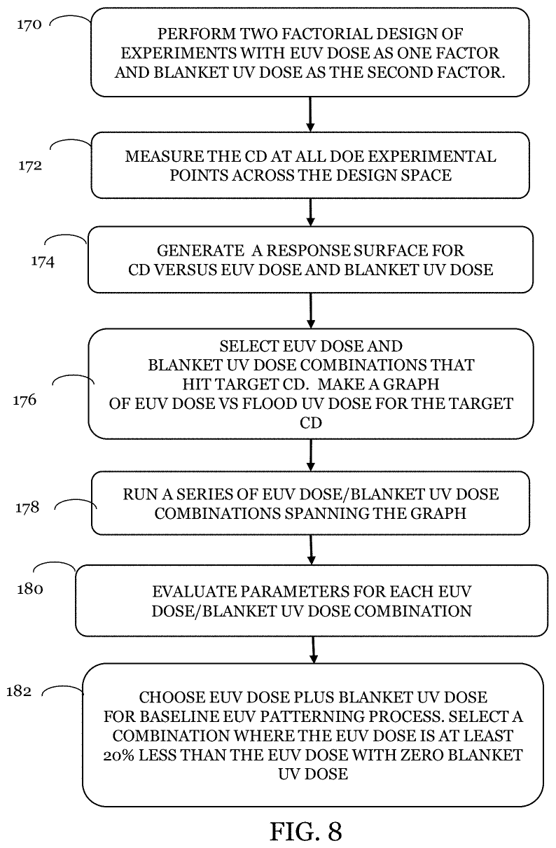

The major steps in a method for selecting the EUV and blanket UV doses that enable higher EUV stepper throughput is described in the flow diagram in FIG. 8. Because the EUV exposure dose and blanket UV exposure dose are strongly coupled, a design of experiments (DOE) approach is selected for illustration. Other methods such as varying the EUV dose and blanket UV dose independently can be used but may be less efficient.

Referring to block 170, a two-factorial design of experiments (DOE) of experiments is performed with EUV dose being selected as the first factor and blanket UV dose being selected as the second factor. One corner point in the DOE experimental space is maximum EUV dose with zero dose blanket UV use case.

Referring next to block 172, the CD is measured on all the experimental points across the DOE space on the wafers run in step 170. This CD may be measured using known techniques in the art.

As next described in block 174, a response surface is generated for the measured CDs versus EUV dose on the first axis and blanket UV dose on the second axis.

As next described with block 176, a set of EUV dose/blanket UV dose combinations is selected that span the EUV range with on target CDs.

As next illustrated in block 178, wafers are processed with the EUV dose/blanket UV dose combinations that span the EUV range with on target CDs.

In block 180, parameters such as cycle time, number of defects, line edge roughness, and CD are evaluated for each of the wafers processed in block 178.

In block 182, an EUV dose/blanket UV dose combination is chosen for the baseline EUV patterning process. As was discussed previously with respect to FIG. 4, the blanket UV dose enables the target CD to be achieved with a lower EUV dose. More wafers can be processed through the EUV stepper as the EUV dose is reduced. It is therefore desirable to select as low an EUV dose possible that produces acceptable line edge roughness and without leaving scum. It is desirable to select a blanket UV dose that reduces the required EUV dose by at least 20% and more preferably by at least 30%.

Scumming can be a problem in EUV patterns, especially in high aspect ratio (narrow and deep) trenches. Scumming can be caused by a variety of factors including (but not limited to): (1) a passivation layer that can be formed during dry development which can lead to an etch stop layer, (2) a chemically different material at the interface of the resist and the underlayer making it harder to remove, (3) non-volatile by products formed during dry development, and (4) stray photons causing reactions in unwanted regions due to stochastics effects (especially when patterning dense features). The alkyl groups in organometallic EUV resists can potentially lead to EUV resist scum with high carbon content.

For a selected developer, the development rate of organometallic EUV resists increases up until a certain additional dose of UV radiation is reached and then decreases with additional UV radiation.

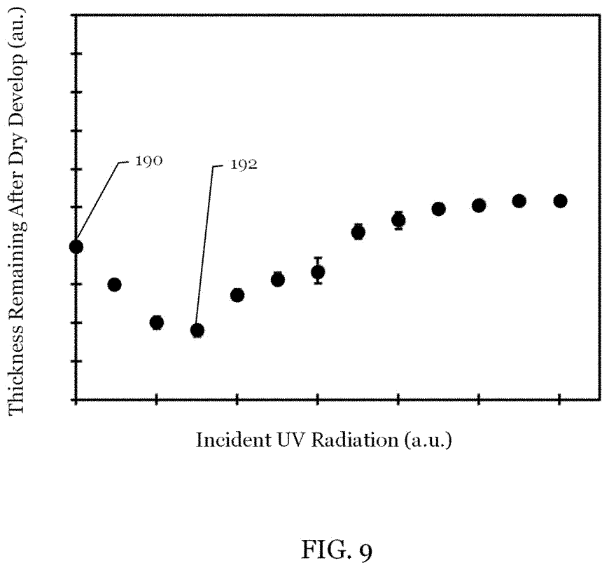

FIG. 9 is a graph of the thickness of a layer of EUV resist that remains on the wafer after a timed develop process relative to UV radiation dose. As UV dose increases from zero (first point 190), the thickness of the remaining resist decreases until it reaches a minimum thickness at second point 192. With higher doses the remaining resist then gets thicker. The decrease in resist thickness with UV dose corresponds to an increase in development rate of the EUV resist. This unusual behavior can be exploited to reduce scumming and to improve contrast.

During the first EUV exposure (FIG. 1C) when printing the pattern 25 to be transferred with EUV light 27, bonds between alkyl ligands 122 and metal oxide cores 120 are broken releasing a first fraction of alkyl ligands from the EUV resist 20. In addition, at high EUV doses, metal oxide networks which may be insoluble are formed.

The second UV exposure 23 (FIG. 1D) is a blanket (no mask) exposure. It exposes the portion of the EUV resist 21 that previously received a dose of EUV light 27 during patterning and also exposes the portion of the EUV resist 20 that previously had significantly less dose.

The second UV exposure 23 increases the total UV dose to the portion of the EUV resist 21 that was previously exposed with EUV light 27. This additional UV dose releases a second fraction of alkyl ligands and also generates more metal oxide networks. These additional metal oxide networks increase the insolubility of the EUV exposed 21 EUV resist.

The second UV exposure 23 also releases second fraction alkyl ligands from the portions of EUV resist 20 that received little or no dose of EUV light 27 during patterning. Additional alkyl ligands are released with increasing dose of the UV light 23. As more alkyl ligands are released the carbon content of the EUV resist 20 is reduced. The reduced carbon content increases the development rate. As the development rate increases, contrast increases and scumming is reduced.

The concentration of cores 120 with attached hydroxy groups increases as UV exposure dose increases and metal oxide networks begin to form. The increase in metal oxide networks reduces the development rate. The increase in metal oxide networks reduces the development rate. These two competing reactions, loss of carbon containing alkyl ligands versus formation of insoluble metal oxide networks is responsible for the minimum second point 192 in the remaining resist curve in FIG. 9.

The development rate of the dry development chemistry in organometallic EUV resists is non-monotonic. The development rate for low EUV exposures increases with additional UV dose and the development rate for higher EUV exposures decreases with additional UV dose. The dose of an additional blanket UV dose can be selected such that the development rate becomes monotonic (e.g., blanket UV dose is added up to a point where the maximum development rate is reached for the lowest dose region on the wafer.) Higher UV doses strictly decrease the dry development rate of the organometallic EUV resist.

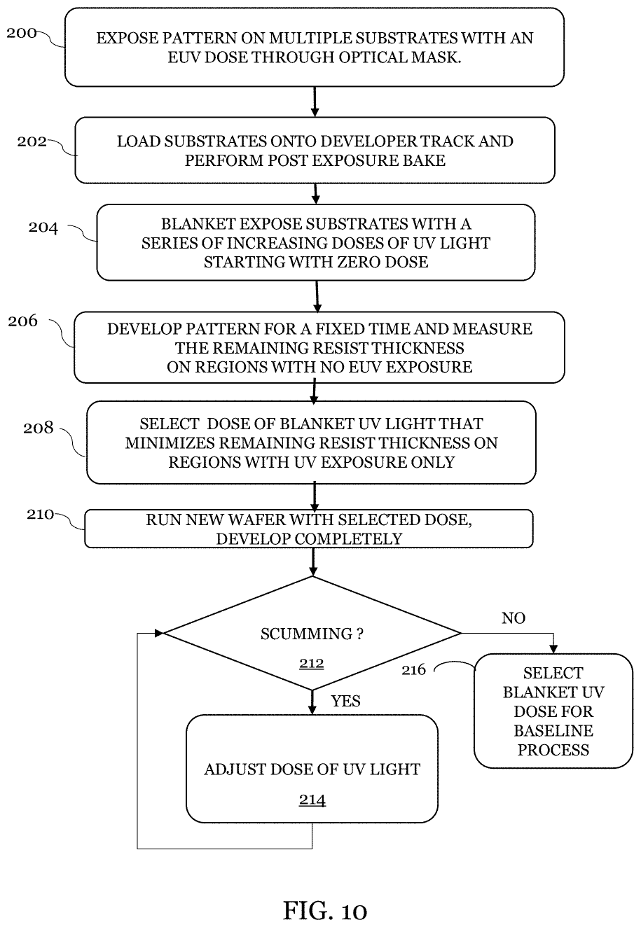

The major steps in a method for reducing scumming 35 (FIG. 1E) in EUV resist patterns is described in the flow diagram in FIG. 10. The method is to first determine the blanket UV dose that maximizes the development rate of the EUV resist and then to run experiments around that point varying the blanket UV dose to find the blanket UV dose with minimum scumming. The UV dose that gives highest contrast is not necessarily the dose that also minimizes scumming.

Referring to block 200, a number of substrates is coated with EUV resist with the baseline dose of EUV light. Next, as in block 202, the substrates are loaded in a coater/developer track and a post exposure bake is performed. Next, in block 204, the substrates are exposed to a blanket UV light with a series of increasing doses of UV light starting with zero dose (i.e., no light).

As next described with block 206, the pattern is developed for a fixed period of time such that some resist remains in regions with little or no EUV exposure and the thickness of the resist that remains in regions with little or no EUV exposure is measured.

As next described with block 208, a blanket UV dose is selected that gives a remaining resist (in a region with zero EUV dose) that is at least 25% thinner than the remaining resist on the substrate with zero EUV dose and zero blanket UV dose. Preferably, a blanket UV dose is selected that gives a remaining resist that is at least 40% thinner. The blanket UV dose that gives the thinnest remaining resist generally also yields the highest contrast but not necessarily the lowest scumming.

Next, in block 210, the wafer is processed with the dose selected in block 208, and fully developed to completely remove resist from regions with zero EUV exposure. Next in block 212, the wafer is inspected for scumming. Scumming may be identified using metrology techniques that may include optical metrology such as scatterometry, ellipsometry, microscopy such as scanning electron microscopy, and other techniques.

If scumming is found after performing block 212, in block 214, the blanket UV exposure dose is adjusted, and the process repeated with the new blanket UV dose until no scum regions are left after processing. Reduced scumming may require a higher blanket UV dose to remove more carbon containing ligands or may require a lower blanket UV dose to reduce the concentration of metal oxide networks.

Blocks 212 and 214 may be repeated until the best condition for scumming is identified. When the best condition is determined, proceed to step 9 217 and select that blanket UV dose for the baseline EUV patterning process.

Example embodiments of the invention are summarized here. Other embodiments can also be understood from the entirety of the specification as well as the claims filed herein.

Example 1. A method including: loading a substrate with a resist including a pattern exposed with a first dose of UV light in the extreme ultraviolet (EUV) radiation region of the UV spectrum onto a developer track; blanket exposing the substrate with a second dose of ultraviolet light radiation in a first UV exposure module; and after the blanket exposing, developing the pattern.

Example 2. The method of example 1, further including performing a post exposure bake before the blanket exposing, the post exposure bake being configured to bake the substrate in an ambient of air or nitrogen for 1 to 3 minutes at a temperature of 50° C. to 250 ° C.

Example 3. The method of example 1, further including performing a post exposure bake after the blanket exposing and before the developing, the post exposure bake being configured to bake the substrate in an ambient of air or nitrogen for 1 to 3 minutes at a temperature of 50° C. to 250° C.

Example 4. The method of one of examples 1 to 3, where a wavelength of light in the first UV exposure module ranges from 130 nm to 300 nm.

Example 5. The method of one of examples 1 to 4, where the first UV exposure module is configured to blanket expose the substrate with a dose of UV light between 1 mJ/cm2 and 100 mJ/cm2.

Example 6. The method of one of examples 1 to 5, further including blanket exposing the substrate with a third dose of UV light after the developing, the third dose being greater than 80 mJ/cm2.

Example 7. A method of forming a pattern on a substrate with a first dose of UV light in the extreme ultraviolet (EUV) region of the UV spectrum, the method including: placing the substrate within an EUV lithography tool, an exposed outer surface of the substrate including an EUV resist; exposing the EUV resist to EUV light transmitted through an optical mask including a pattern to be transferred; blanket exposing the EUV resist on the substrate with a second dose of UV light; and after the blanket exposing, developing the EUV resist to form the pattern to be transferred.

Example 8. The method of example 7, further including subjecting the substrate to a post exposure bake after exposing to the EUV light and before blanket exposing to the UV light.

Example 9. The method of one of examples 7 or 8, further including: determining a first dose of EUV light for patterning a reference EUV resist to a target linewidth by using only an EUV exposure without any intervening UV exposure; and determining a second dose of EUV light for patterning the EUV resist to the target linewidth by using the EUV exposure and a blanket UV exposure, the second dose being at least 20% less than the first dose, where exposing the EUV resist includes exposing the EUV resist at the second dose.

Example 10. The method of one of examples 7 to 9 further including selecting a blanket UV exposure dose for the blanket exposing such that the second dose is at least 30% less that the first dose.

Example 11. The method of one of examples 7 to 10, further including: after exposing the substrate with EUV light, loading the substrate into a developer track, where the blanket exposing, and the developing are performed in the developer track.

Example 12. The method of one of examples 7 to 11 where the second dose of blanket UV light has a wavelength of 130 nm to 300 nm and the exposure dose is 1 mJ/cm2 to 100 mJ/cm2.

Example 13. The method of one of examples 7 to 12, further including: subjecting the substrate to a post exposure bake between the blanket exposing and the developing.

Example 14. The method of one of examples 7 to 13, where the EUV resist is an organometallic EUV resist.

Example 15. The method of one of examples 7 to 14, further including: after the developing, blanket exposing the substrate with a third dose of UV light with an exposure dose greater than 80 mJ/cm2.

Example 16. The method of one of examples 7 to 15, further including: determining a first dose of EUV light for patterning a reference EUV resist to a target linewidth by using only a EUV exposure without any intervening blanket UV exposure; exposing a reference substrate including a reference EUV resist to the EUV light transmitted through the optical mask including the pattern to be transferred and developing, without any intervening blanket UV exposure, the exposed reference EUV resist to form the pattern to be transferred; performing a timed develop that leaves a layer of resist remaining in regions not exposed with EUV light; measuring a remaining first resist thickness of the reference EUV resist in a region not exposed with EUV light after the developing the exposed reference EUV resist; exposing a plurality of test substrates, each test substrate including a test EUV resist, to the EUV light transmitted through the optical mask including the pattern to be transferred, blanket exposing the exposed test EUV resist on each of the test substrates with UV light of a different UV dose; and performing the timed develop on each of the test substrates to form the pattern to be transferred; measuring remaining resist thicknesses for each test substrate on the region exposed with blanket UV and not exposed with EUV after the timed developing of the exposed test EUV resist on each of the test substrates; and selecting a dose of UV light for the blanket exposing of the exposed EUV resist on the substrate, the selected dose corresponding to a thickness of the exposed test EUV resist on a region of the substrate exposed with blanket UV light and not exposed with EUV that is at least 25% thinner than the first resist thickness.

Example 17. The method of one of examples 7 to 16, where the selected dose corresponds to a thickness of the exposed test EUV resist on a region of the substrate exposed with blanket UV light and not exposed with EUV that is at least 40% thinner than the first remaining post develop resist thickness.

Example 18. The method of one of examples 7 to 17, further including: patterning a substrate with the selected dose and fully developing the pattern to remove resist from regions with no EUV exposure; inspecting the pattern for scumming; repeating adjusting the selected dose of blanket UV, forming a pattern on a substrate, and inspecting the pattern for scumming, until a dose of blanket UV that minimizes scumming is determined; and selecting the adjusted selected dose for the baseline EUV patterning process.

Example 19. The method of one of examples 7 to 18, where developing the exposed EUV resist includes a dry developing process with a gas including hydrogen and bromine.

Example 20. A method of processing a substrate, the method including: having an organometallic photoresist disposed on a layer to be patterned formed on the substrate, the organometallic photoresist including alkyl ligands attached to metal oxide particles; forming photoproducts by removing a first fraction of the alkyl ligands from portions of the organometallic photoresist to be developed; condensing the photoproducts to form a metal oxide network in the exposed portion of the organometallic photoresist; removing a second fraction of the alkyl ligands from the metal oxide network in the organometallic photoresist from the exposed portion and from the unexposed portion of the organometallic photoresist; and after removing the second fraction of the alkyl ligands, developing the organometallic photoresist to form a patterned organometallic photoresist.

Example 21. The method of example 20, where forming the photoproducts includes exposing the organometallic photoresist to a first dose of UV light having a first wavelength in the extreme ultraviolet (EUV) region of the UV spectrum through an optical mask including a pattern to be formed on the organometallic photoresist, where removing the second fraction of the alkyl ligands includes exposing the exposed and the unexposed organometallic photoresist to a second UV radiation without the optical mask and having a second wavelength, the second wavelength being at least ten times longer than the first wavelength.

Example 22. The method of one of examples 20 or 21, where the second UV radiation is performed in a UV light module integrated into a developer track.

Example 23. The method of one of examples 20 to 22, further including after the developing, blanket exposing the substrate with a third UV dose having the second wavelength for greater than 1 minute and with a dose greater than 80 mJ/cm2.

Example 24. The method of one of examples 20 to 23, where condensing the photoproducts includes subjecting the substrate to a post exposure bake process.

Example 25. The method of one of examples 20 to 24, where the post exposure bake process includes heating the substrate to 50° C. to 250° C. in air for a time of 1 min. to 3 min.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method comprising:
loading a substrate with a resist comprising a pattern exposed with a first dose of UV light in the extreme ultraviolet (EUV) radiation region of the UV spectrum onto a developer track;
blanket exposing the substrate with a second dose of ultraviolet light radiation in a first UV exposure module; and
after the blanket exposing, developing the pattern.

2. The method of claim 1, further comprising performing a post exposure bake before the blanket exposing, the post exposure bake being configured to bake the substrate in an ambient of air or nitrogen for 1 to 3 minutes at a temperature of 50° C. to 250° C.

3. The method of claim 1, further comprising performing a post exposure bake after the blanket exposing and before the developing, the post exposure bake being configured to bake the substrate in an ambient of air or nitrogen for 1 to 3 minutes at a temperature of 50° C. to 250° C.

4. The method of claim 1, wherein a wavelength of light in the first UV exposure module ranges from 130 nm to 300 nm.

5. The method of claim 1, wherein the first UV exposure module is configured to blanket expose the substrate with a dose of UV light between 1 mJ/cm² and 100 mJ/cm².

6. The method of claim 1, further comprising blanket exposing the substrate with a third dose of UV light after the developing, the third dose being greater than 80 mJ/cm².

7. A method of forming a pattern on a substrate with a first dose of UV light in the extreme ultraviolet (EUV) region of the UV spectrum, the method comprising:
placing the substrate within an EUV lithography tool, an exposed outer surface of the substrate comprising an EUV resist;
exposing the EUV resist to EUV light transmitted through an optical mask comprising a pattern to be transferred;
blanket exposing the EUV resist on the substrate with a second dose of UV light; and
after the blanket exposing, developing the EUV resist to form the pattern to be transferred.

8. The method of claim 7, further comprising subjecting the substrate to a post exposure bake after exposing to the EUV light and before blanket exposing to the UV light.

9. The method of claim 7, further comprising:
determining a first dose of EUV light for patterning a reference EUV resist to a target linewidth by using only an EUV exposure without any intervening UV exposure; and
determining a second dose of EUV light for patterning the EUV resist to the target linewidth by using the EUV exposure and a blanket UV exposure, the second dose being at least 20% less than the first dose,
wherein exposing the EUV resist comprises exposing the EUV resist at the second dose.

10. The method of claim 9 further comprising selecting a blanket UV exposure dose for the blanket exposing such that the second dose is at least 30% less that the first dose.

11. The method of claim 7, further comprising:
after exposing the substrate with EUV light, loading the substrate into a developer track, wherein the blanket exposing, and the developing are performed in the developer track.

12. The method of claim 7 wherein the second dose of blanket UV light has a wavelength of 130 nm to 300 nm and the exposure dose is 1 mJ/cm² to 100 mJ/cm².

13. The method of claim 7, further comprising:
subjecting the substrate to a post exposure bake between the blanket exposing and the developing.

14. The method of claim 7, wherein the EUV resist is an organometallic EUV resist.

15. The method of claim 7, further comprising:
after the developing, blanket exposing the substrate with a third dose of UV light with an exposure dose greater than 80 mJ/cm².

16. The method of claim 7, further comprising:
determining a first dose of EUV light for patterning a reference EUV resist to a target linewidth by using only a EUV exposure without any intervening blanket UV exposure;
exposing a reference substrate comprising a reference EUV resist to the EUV light transmitted through the optical mask comprising the pattern to be transferred and developing, without any intervening blanket UV exposure, the exposed reference EUV resist to form the pattern to be transferred;
performing a timed develop that leaves a layer of resist remaining in regions not exposed with EUV light;
measuring a remaining first resist thickness of the reference EUV resist in a region not exposed with EUV light after the developing the exposed reference EUV resist;
exposing a plurality of test substrates, each test substrate comprising a test EUV resist, to the EUV light transmitted through the optical mask comprising the pattern to be transferred, blanket exposing the exposed test EUV resist on each of the test substrates with UV light of a different UV dose; and performing the timed develop on each of the test substrates to form the pattern to be transferred;
measuring remaining resist thicknesses for each test substrate on the region exposed with blanket UV and not exposed with EUV after the timed developing of the exposed test EUV resist on each of the test substrates; and
selecting a dose of UV light for the blanket exposing of the exposed EUV resist on the substrate, the selected dose corresponding to a thickness of the exposed test EUV resist on a region of the substrate exposed with blanket UV light and not exposed with EUV that is at least 25% thinner than the first resist thickness.

17. The method of claim 16, wherein the selected dose corresponds to a thickness of the exposed test EUV resist on a region of the substrate exposed with blanket UV light and not exposed with EUV that is at least 40% thinner than the first remaining post develop resist thickness.

18. The method of claim 16, further comprising:
patterning a substrate with the selected dose and fully developing the pattern to remove resist from regions with no EUV exposure;
inspecting the pattern for scumming;
repeating adjusting the selected dose of blanket UV, forming a pattern on a substrate, and inspecting the pattern for scumming, until a dose of blanket UV that minimizes scumming is determined; and
selecting the adjusted selected dose for the baseline EUV patterning process.

19. The method of claim 7, wherein developing the exposed EUV resist comprises a dry developing process with a gas comprising hydrogen and bromine.

20. A method of processing a substrate, the method comprising:
having an organometallic photoresist disposed on a layer to be patterned formed on the substrate, the organometallic photoresist comprising alkyl ligands attached to metal oxide particles;
forming photoproducts by removing a first fraction of the alkyl ligands from portions of the organometallic photoresist to be developed;
condensing the photoproducts to form a metal oxide network in the exposed portion of the organometallic photoresist;
removing a second fraction of the alkyl ligands from the metal oxide network in the organometallic photoresist from the exposed portion and from the unexposed portion of the organometallic photoresist; and
after removing the second fraction of the alkyl ligands, developing the organometallic photoresist to form a patterned organometallic photoresist.

21. The method of claim 20, wherein forming the photoproducts comprises exposing the organometallic photoresist to a first dose of UV light having a first wavelength in the extreme ultraviolet (EUV) region of the UV spectrum through an optical mask comprising a pattern to be formed on the organometallic photoresist, wherein removing the second fraction of the alkyl ligands comprises exposing the exposed and the unexposed organometallic photoresist to a second UV radiation without the optical mask and having a second wavelength, the second wavelength being at least ten times longer than the first wavelength.

22. The method of claim 21, wherein the second UV radiation is performed in a UV light module integrated into a developer track.

23. The method of claim 20, further comprising after the developing, blanket exposing the substrate with a third UV dose having the second wavelength for greater than 1 minute and with a dose greater than 80 mJ/cm².

24. The method of claim 20, wherein condensing the photoproducts comprises subjecting the substrate to a post exposure bake process.

25. The method of claim 24, wherein the post exposure bake process comprises heating the substrate to 50° C. to 250° C. in air for a time of 1 min. to 3 min.
